(19) United States
(12) Patent Application Publication
(10) Pub. No.: US 2009/0210758 A1
(43) Pub. Date: Aug. 20, 2009

(54) METHOD FOR REDUCING DATA ERROR WHEN FLASH MEMORY STORAGE DEVICE USING COPY BACK COMMAND

(75) Inventors: Chun-Hao Huang, Taipei (TW); Chia-Hsin Chen, Taipei (TW); Ming-Che Liu, Taipei (TW)

Correspondence Address: KIRTON AND MCCONKIE, 60 EAST SOUTH TEMPLE,, SUITE 1800, SALT LAKE CITY, UT, 84111, US

(73) Assignee: ASMEDIA TECHNOLOGY INC., Taipei (TW)

(21) Appl. No.: 12/241,307

(22) Filed: Sep. 30, 2008

(30) Foreign Application Priority Data
Feb. 15, 2008 (TW) 097105394

(51) Int. Cl. G11C 29/00

(52) U.S. Cl. 714/718

(57) ABSTRACT

A method for a flash memory storage device to use a copy back command includes the following steps. The method includes the step of copying a data in a first block of a flash memory to a buffer outside the flash memory, checking if the data in the buffer is correct, and copying the data in the first block of the flash memory to a second block in the flash memory when the data in the buffer is correct.

### FIELD OF THE INVENTION

The invention relates to a method for accessing data, and more particularly, a method for accessing data in a flash memory storage device.

### BACKGROUND OF THE INVENTION

A flash memory has advantages such as having a high memory density, being nonvolatile and shockproof. Therefore, a flash memory storage device which is formed by the flash memory cooperated with a control circuit has been widely used. The flash memory storage device is, for example, a thumb drive, a CompactFlash, a Secure Digital, a Multi Media Card and so on.

FIG. 1 is a schematic diagram showing a flash memory storage device. The flash memory storage device 10 includes a control circuit 12 and a flash memory 16. The flash memory 16 can be divided into many blocks, and each block includes a plurality of pages. The host 30 can access data in the flash memory 10 through a host bus 20. The host bus 20 can be a CompactFlash (CF) bus, a Secure Digital (SD) bus, a Multi Media Card (MMC) bus, a universal serial bus (USB), an IEEE 1394 bus or other similar bus.

An internal bus 18 in the flash memory storage device 10 is connected between the control circuit 12 and the flash memory 16. The control circuit 12 further includes a buffer 13 and an error correcting codes (ECC) unit 14. When the host 30 writes the data to the flash memory 16, the ECC unit 14 performs an operation on the data and produces an error correcting code (ECC), the control circuit 12 sends a write command to the flash memory 16 and sends the write data together with the ECC to the flash memory through the internal bus 18. The main purpose of the buffer 13 is to store the data temporarily.

When the host reads the data in the flash memory 16, the control circuit 12 sends a read command to the flash memory 16. Therefore, the flash memory 16 outputs both the read data and the ECC to the control circuit 12 through the internal bus 18. Then, the ECC unit 14 can detect whether the read data is correct or not according to the ECC. When the read data is detected to be correct, the control circuit 12 sends the read data to the host through the host bus 20. When the read data is incorrect, the control circuit 12 corrects the read data according to the ECC produced by the ECC unit and sends the corrected read data to the host through the host bus 20. The ECC may be a Hamming code, a Reed Solomon code or other kinds of ECC.

To increase the access speed of the flash memory 16, the transfer of a data block in the flash memory 16 can be achieved by a copy back command. That is, when the control circuit 12 needs to transfer the data in the first block (old block) of the flash memory 16 to the second block (new block), as long as the control circuit 12 sends a copy back command to the flash memory 16, the flash memory 16 can finish the action of transferring the data in the first block to the second block by itself.

When the flash memory 16 finishes transferring the data in the first block to the second block by itself, the data does not pass through the control circuit 12. Therefore, the ECC unit 14 cannot ensure the correctness of the data. That is, the correctness of the data in the second block cannot be known. Aiming at the disadvantage, the American U.S. Pat. No. 7,187,583 discloses a “method for reducing data error when flash memory storage device using copy back command”.

FIG. 2A and FIG. 2B are a flow chart and a schematic diagram showing the conventional method for reducing the data error when the flash memory uses the copy back command. In FIG. 2A, in step 110, the control circuit 12 sends the copy back command to the flash memory 16. That is, the data in the first block of the flash memory 16 can be transferred to the second block. The first block is the old block and the second block is the new block.

Then, in step 120, the control circuit 12 sends a read command to store the data page that does not need to be amended in the second block (new block) to the buffer 13 outside the flash memory 16.

In step 130, the control circuit 12 determines whether the data in the buffer is incorrect by the ECC unit 14. That is, the ECC unit 14 can determine whether the data in the buffer is correct by an error correction rule.

When the data is correct, step 160 is performed. That is, the next command or task is executed. If the data is incorrect, the ECC unit 14 automatically corrects the incorrect data in the buffer to be correct data. Then, the control circuit 12 performs step 140, that is, to execute the data write command to write the data in the buffer 13 to a third block. The third block is another new block.

After finishing the step 140, the control circuit 12 needs to erase the data in the second block of the flash memory 16. Therefore, the control circuit 12 then performs step 150, that is, to execute an erase command to erase the data in the second block. At last, the control circuit 12 performs step 160.

As shown in FIG. 2B, to reduce the data error when the flash memory uses the copy back command, the control circuit 12 executes the copy back command first to make the data in the first block (old block) 111 of the flash memory 16 to store to the second block (new block) 112.

Then, the control circuit 12 sends a read command to copy the data in the second block (new block) of the flash memory 16 to the buffer 13. When the data in the buffer 13 is determined to be correct by the ECC unit 14, the control circuit 12 can confirm that the data in the second block (new block) is correct after executing the copy back command.

However, when the data in the buffer 13 is determined to be incorrect by the ECC unit, the ECC unit 14 needs to correct the data in the buffer 13 in advance. After that, the control circuit 12 sends a data write command to write the data in the buffer 13 to a third block (another new block) 113. Then, the command of erasing the data in the second block is executed. At last, the control circuit 12 can confirm that the data in the third block (another new block) 113 is correct.

After the control circuit 12 executes the copy back command, to confirm whether the data in the second block 112 is correct, the data in the second block 112 should be read again to the buffer 13 outside the control circuit 12, and the ECC unit 14 should be used to confirm whether the data in the buffer 13 is correct or not to determine whether the data in the second block 112 is correct.

When the data in the second block 112 is incorrect, the control circuit 12 should store the corrected data in the buffer 13 to a third block (another new block) 113 and erase the data in the second block (new block) 112. Thus, the control circuit 12 may confirm that the data in the third block (another new block) 113 is correct after executing the copy back command.

The flow path above is not the best way for correcting the data. Therefore, the main objective of the invention is to solve the problem that how to make the flash memory execute the copy back command and how to confirm the correctness of the data effectively.

### SUMMARY OF THE INVENTION

The invention provides a method for a flash memory storage device to use a copy back command. The method includes the steps of copying a data in a first block of a flash memory to a buffer outside the flash memory; checking if the data in the buffer is correct; and copying the data in the first block of the flash memory to a second block in the flash memory when the data in the buffer is correct.

Another aspect of the invention provides a flash memory storage device using a copy back command. The flash memory storage device includes a control circuit and a flash memory connected to the control circuit. The control circuit has a buffer and an error correcting codes (ECC) unit, and it copies the data in the first block of the flash memory to the buffer. If the ECC unit checks that the data in the buffer is correct, the control unit sends a copy back command to the flash memory to copy the data in the first block of the flash memory to a second block of the flash memory.

Compared with the conventional method, the invention has a beneficial effect that the control circuit does not need to erase the second block. Moreover, in the invention, an additional third block (another new block) in the flash memory is not needed. Therefore, in the invention, the flash memory copy back command can be executed effectively, and correctness of the data can be achieved.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a schematic diagram showing a flash memory storage device;

FIG. 2A and FIG. 2B are a flow chart and a schematic diagram showing the conventional method for reducing data error when the flash memory uses the copy back command; and

FIG. 3A and FIG. 3B are a flow chart and a schematic diagram showing the method of the invention for reducing data error when the flash memory uses the copy back command.

### DETAILED DESCRIPTION OF THE PREFERRED EMBODIMENT

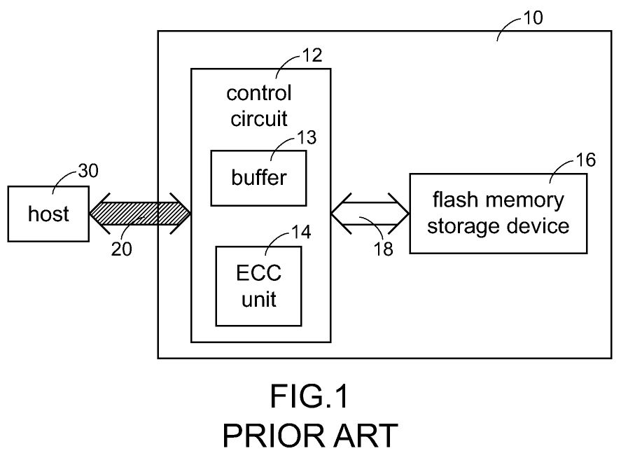

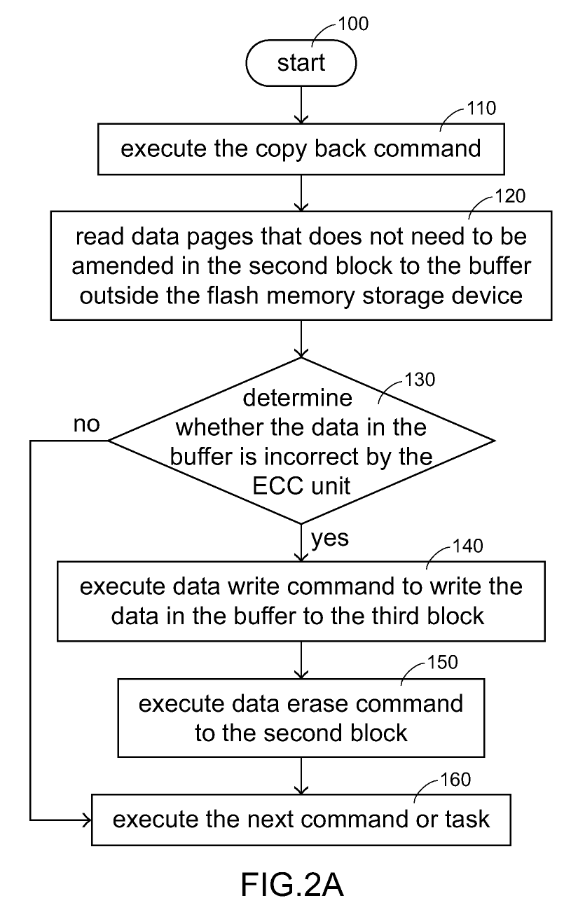

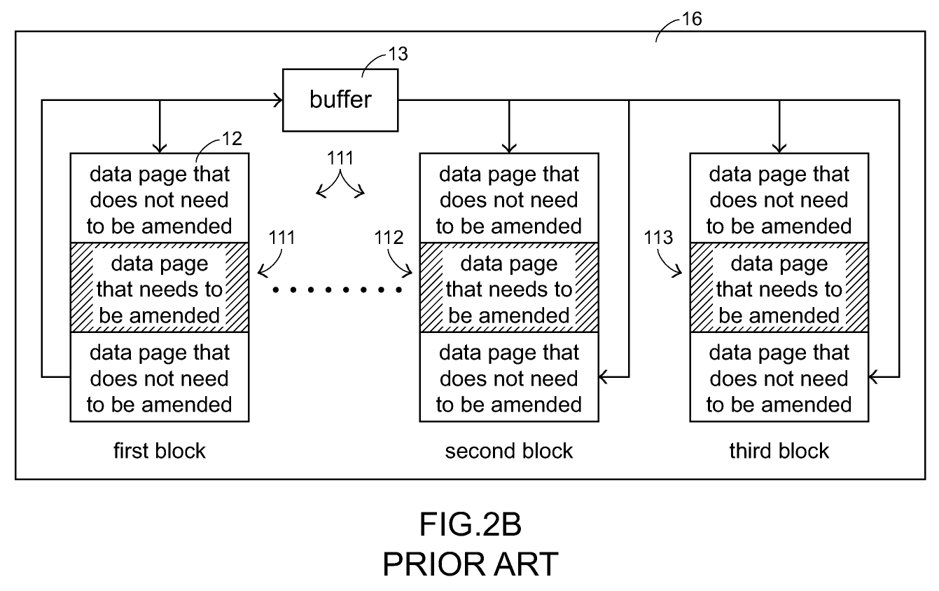

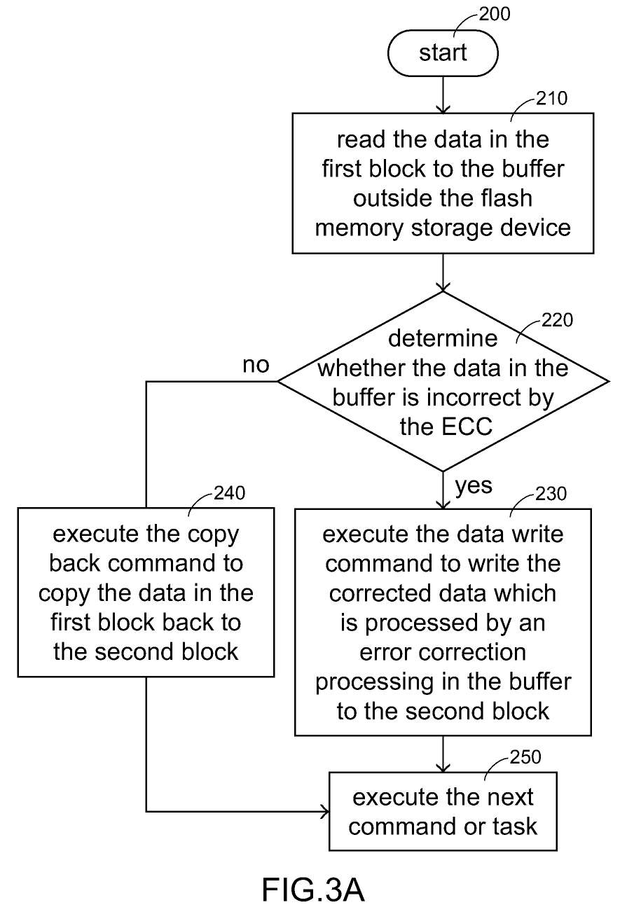

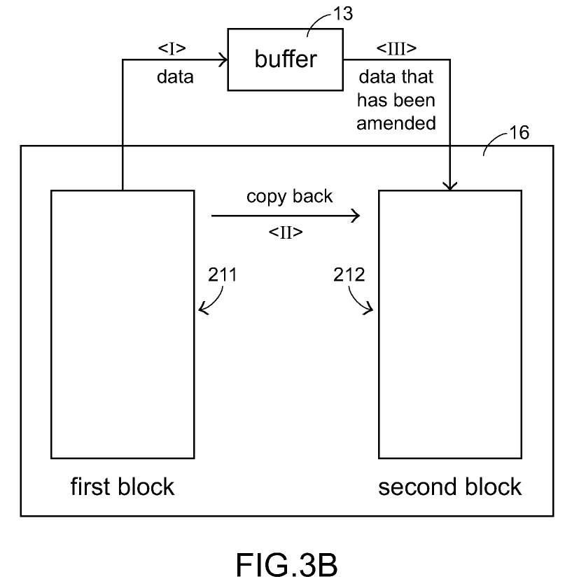

FIG. 3A and FIG. 3B are a flow chart and a schematic diagram showing the method for reducing data error when the flash memory uses the copy back command according to an embodiment of the invention. As shown in FIG. 3A, FIG. 3B and FIG. 1, before the control circuit 12 executes the copy back command to copy the data in the first block (old block) to the second block (new block), step 210 is performed first. That is, the control circuit 12 sends a read command to copy the data in the first block (old block) to the buffer 13 outside the flash memory 16

Then, in step 220, the control circuit 12 determines whether the data in the buffer 13 is incorrect by the ECC unit 14. That is, the ECC unit 14 can determine whether the data in the buffer 13 from the first block is correct according to an error correction rule.

When the data in the buffer 13 is correct, step 240 is performed. That is, the control circuit executes the copy back command to copy the data in the first block (old block) of the flash memory 16 to the second block (new block) of the flash memory 16. Therefore, the control circuit 12 can confirm that the data in the second block (new block) is correct after executing the copy back command. At last, the control circuit 12 performs step 250, that is, to execute the next command or task.

When the data in the buffer 13 is incorrect, the ECC unit 14 first performs an error correction processing and corrects the data in the buffer 13. After that, the control circuit 12 performs step 230, and the control circuit 12 does not send the copy back command. That is, the control circuit 12 sends a data write command to write the corrected data in the buffer 13 from ECC unit 14, and the corrected data copy to a second block (new block) from the buffer 13. Since the ECC unit 14 corrects the data in the buffer 13 by an error correction processing, the control circuit 12 can confirm that the data in the second block (new block) is correct. At last, the control circuit 12 performs step 250, that is, to execute the next command or task.

According to FIG. 3B, for reducing data error when the flash memory uses the copy back command, before the control circuit 12 executes the copy back command to copy the data in the first block (old block) 211 to the second block (new block) 212, the data in the first block (old block) 211 needs to be confirmed whether it is correct. That is, as shown by path (I), first, the data in the first block (old block) 211 is copied to the buffer 13 outside the flash memory 16, and the data in the buffer 13 is determined to be correct or not by the ECC unit 14 (see FIG. 1). Therefore, the correctness of the data in the first block (old block) 211 is confirmed. If the data in the buffer 13 is incorrect, it also may be corrected by the ECC unit 14 to increase the correctness.

When the data in the first block (old block) 211 is correct, as shown by path (II), the control circuit 12 (see FIG. 1) then sends the copy back command to the flash memory 16 to copy the data in the first block (old block) 211 to the second block (new block) 212.

When the data in the first block (old block) 211 is incorrect, as shown by path (III), the control circuit 12 does not send the copy back command, and it sends the data write command to the flash memory 16. The buffer 13 of the control circuit 12 transfers the correct data to the second block (new block) 212.

Compared with the conventional method, the control circuit 12 according to the embodiment of the invention does not need to erase the second block. Moreover, according to the embodiment of the invention, an additional third block (another new block) in the flash memory 16 is not needed. Therefore, according to the embodiment of the invention, the flash memory copy back command can be executed effectively, and the correctness of the data can be achieved.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A method for a flash memory storage device to use a copy back command, comprising:
copying a data in a first block of a flash memory to a buffer outside the flash memory;
checking whether the data in the buffer is correct; and
copying the data in the first block of the flash memory to a second block in the flash memory when the data in the buffer is correct.

2. The method according to claim 1, wherein when the data in the buffer is incorrect, the data in the buffer is processed by an error correction processing to generate a corrected data, then the corrected data is copied to the second block in the flash memory.

3. The method according to claim 1, wherein the step of checking whether the data in the buffer is correct is checking according to a Hamming code correction rule.

4. The method according to claim 1, wherein the step of checking whether the data in the buffer is correct is checking according to a Reed Solomon code correction rule.

5. A flash memory storage device using a copy back command, comprising:
a control circuit having a buffer and an error correcting code (ECC) unit; and
a flash memory connected to the control circuit;
wherein the control unit copies a data in a first block of the flash memory to the buffer, and when the ECC unit checks that the data in the buffer is correct, the control unit sends a copy back command to the flash memory to copy the data in the first block of the flash memory to a second block of the flash memory.

6. The flash memory storage device using the copy back command according to claim 5, wherein when the ECC unit detects the data in the buffer is incorrect, the control circuit processes the data in the buffer by an error correction processing to generate a corrected data, then the corrected date is copied to the second block of the flash memory.

7. The flash memory storage device using the copy back command according to claim 5, wherein the control circuit is connected to the flash memory with an internal bus.

8. The flash memory storage device using the copy back command according to claim 5, wherein the ECC unit checks whether the data in the buffer is correct according to a Hamming code correction rule.

9. The flash memory storage device using the copy back command according to claim 5, wherein the ECC unit checks whether the data in the buffer is correct according to a Reed Solomon code correction rule.
